(19) United States
(12) Patent Application Publication
(10) Pub. No.: US 2026/0101498 A1
(43) Pub. Date: Apr. 9, 2026

(54) THREE-DIMENSIONAL SEMICONDUCTOR DEVICE

(71) Applicant: Winbond Electronics Corp., Taichung City (TW)

(72) Inventors: Hung-Yu WEI, Kaohsiung City (TW); Wei-Che CHANG, Taichung City (TW)

(21) Appl. No.: 19/354,185

(22) Filed: Oct. 9, 2025

(30) Foreign Application Priority Data
Oct. 9, 2024 (TW) 113138464

(51) Int. Cl. H10B 12/00

(52) U.S. Cl. CPC H10B 12/30; H10B 12/05

(57) ABSTRACT

A three-dimensional semiconductor device includes a stack of alternating memory cell layers and insulating layers over a substrate, and several bit lines formed on the substrate and separated from each other. The bit lines and the memory cell layers define an array of stacked memory cells that includes several memory cells. One of the memory cells includes a body, a gate structure and a conductive portion. The body that is on the substrate has a first surface and a second surface opposite the first surface. One side of the body is connected to one of the bit lines. The gate structure and the conductive portion are formed on the opposite first and second surfaces. The conductive portion is formed between adjacent memory cell layers and is in direct contact with the body.

### CROSS REFERENCE TO RELATED APPLICATIONS

This Application claims priority of Taiwan Patent Application No. 113138464, filed on Oct. 9, 2024, the entirety of which is incorporated by reference herein.

### BACKGROUND OF THE INVENTION

### Field of the Invention

The present invention relates to a semiconductor device, and, in particular, it relates to a three-dimensional semiconductor device having an array of stacked memory cells.

### Description of the Related Art

The manufacturing technology of semiconductor devices is developing towards miniaturization of device size. In order to effectively increase the integration of components in semiconductor devices and improve their performance, the manufacturing technology of semiconductor devices has increased component density by moving from two-dimensional planes to three-dimensional stacking. However, many challenges have also arisen. For example, in a known semiconductor device having a three-dimensional stacked memory cell array, charges can be stored in a capacitor element through a floating body. Although the write/erase efficiency can be improved by using the floating body, an excess charge may accumulate in the body and cause leakage current.

### BRIEF SUMMARY OF THE INVENTION

Some embodiments of the present disclosure provide a three-dimensional semiconductor device, including a plurality of memory cell layers and a plurality of insulating layers disposed in an alternating manner above a substrate, and a plurality of bit lines disposed on the substrate and spaced apart from each other. The bit lines and the memory cell layers define a stacked memory cell array. The memory cell array includes a plurality of memory cells. Each memory cell includes a body, a gate structure, and a conductive portion. The body located above the substrate has a first surface and a second surface opposite to each other, and one side of the body is connected to one of the bit lines. The gate structure and the conductive portion are respectively located on opposite surfaces of the body. The conductive portion is located between adjacent memory cell layers and is in direct contact with the body.

Some embodiments of the present disclosure provide a three-dimensional semiconductor device, including a plurality of memory cell layers and a plurality of insulating layers disposed in an alternating manner above a substrate. The memory cell layers include a stacked memory cell array, and one of the memory cell layers includes a plurality of bodies, a gate structure and a conductive portion. Each body has a first surface and a second surface that are opposite each other, wherein the bodies extend in a first direction and are spaced apart from each other in a second direction. The gate structure extends in the second direction and is located on the first surfaces of the bodies. The conductive portion extends in the second direction, and the surface of the conductive portion is in contact with the second surfaces of the bodies that are opposite to the first surfaces. The other surface of the conductive portion is in contact with the first surfaces of the bodies of the adjacent memory cell layer.

### BRIEF DESCRIPTION OF THE DRAWINGS

FIG. 1 is a partial perspective view of a three-dimensional semiconductor device having a horizontal word line stacking type according to some embodiments of the present disclosure.

FIG. 2 is a schematic cross-sectional view of memory cells of adjacent memory cell layers in the three-dimensional semiconductor device of FIG. 1.

FIG. 3 is a top view of adjacent memory cells in the same column of the memory layer of the 3D flash memory device.

FIGS. 3A-3I are schematic diagrams of a group of adjacent memory cells of a three-dimensional semiconductor device at multiple intermediate manufacturing stages according to some embodiments of the present disclosure.

FIG. 4 is a schematic cross-sectional view of gate structures, conductive portions, and multiple bodies of adjacent memory cell layers in a semiconductor device according to some embodiments of the present disclosure.

FIGS. 5A and 5B are schematic cross-sectional views of three-dimensional semiconductor devices according to some embodiments of the present disclosure.

FIG. 6 is a schematic cross-sectional view of adjacent memory cells in a three-dimensional semiconductor device with a vertical word line stacking type according to some embodiments of the present disclosure.

FIGS. 7A-7D are schematic diagrams of two groups of adjacent memory cells of a three-dimensional semiconductor device at multiple intermediate manufacturing stages according to some embodiments of the present disclosure.

### DETAILED DESCRIPTION OF THE INVENTION

The semiconductor device provided in some embodiments of the present disclosure is, for example, a dynamic random access memory (DRAM) device, or other applicable semiconductor devices. The semiconductor device of the embodiment has a stacked memory cell array, and a common conductive portion directly in contact with the bodies is disposed between the opposite surfaces of the bodies of two adjacent memory cells. The embodiment can be applied to a three-dimensional semiconductor device of a horizontal word line stacking type or a vertical word line stacking type.

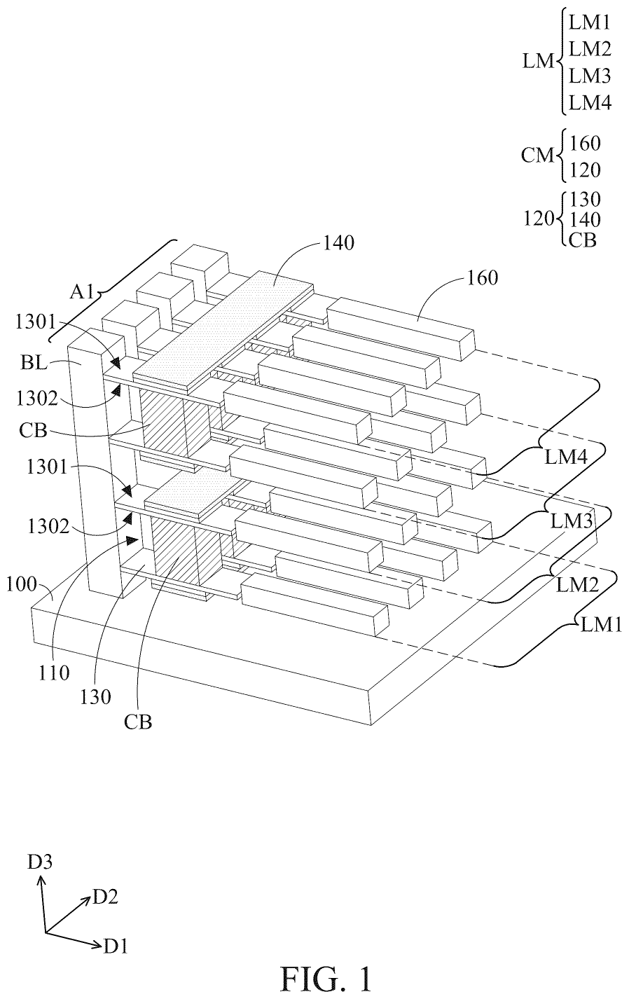

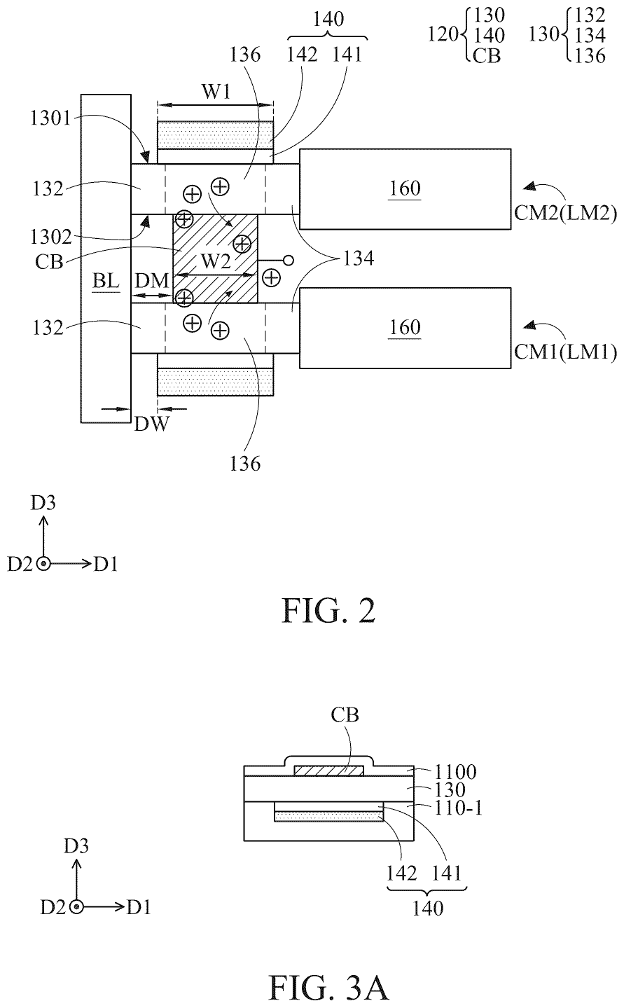

FIG. 1 is a partial perspective view of a three-dimensional semiconductor device having a horizontal word line stacking type according to some embodiments of the present disclosure. FIG. 2 is a schematic cross-sectional view of memory cells of adjacent memory cell layers in the three-dimensional semiconductor device of FIG. 1. Furthermore, FIG. 2 omits showing the substrate, and the relative positions of the substrate and other components can be referred to in FIG. 1.

As shown in FIG. 1, the three-dimensional semiconductor device includes a substrate 100, with a plurality of memory cell layers LM and a plurality of insulating layers 110 stacked in an alternating manner on the substrate 100. In this embodiment, four memory cell layers LM1, LM2, LM3 and LM4 are stacked from bottom to top on the substrate 100 to illustrate the horizontal word line structure. Furthermore, the material of the substrate 100 includes, for example, silicon, gallium arsenide, gallium nitride, germanium silicide, silicon on insulator, other suitable materials or combinations thereof. The insulating layer 110 includes, for example, silicon oxide or other suitable materials.

The three-dimensional semiconductor device further includes a plurality of bit lines BL formed on the substrate 100 and spaced apart from each other. The bit lines BL penetrate the memory cell layers LM1-LM4 and the insulating layer 110, and define a stacked memory cell array with the memory cell layers. The stacked memory cell array includes a plurality of memory cells CM arranged in a three-dimensional stacking manner.

In some embodiments, each memory cell layer LM has a plurality of bodies 130, a gate structure 140 and a conductive portion CB. The bodies 130 extend in the direction D1 and are spaced apart from each other in the direction D2. The direction D2 is different from (e.g., perpendicular to) the direction D1. The body 130 has opposite surfaces 1301 and 1302.

In some embodiments, the gate structure 140 and the conductive portion CB have the same extension direction, for example, both extend in the direction D2. The gate structure 140 and the conductive portion CB are respectively located on different surfaces of the body 130. Furthermore, the conductive portion CB of the embodiment is located between the memory cells of adjacent memory cell layers and is in direct contact with the surfaces of the bodies 130 of the memory cells.

Taking a group of adjacent memory cell layers LM1 and LM2 as an example, as shown in FIG. 2, the surface 1302 of the body 130 of the memory cell CM1 and the surface 1301 of the body 130 of the memory cell CM2 can be regarded as the outer surfaces of the bodies 130 of this group of memory cell layers. The surface 1301 of the body 130 of the memory cell CM1 and the surface 1302 of the body 130 of the memory cell CM2 can be regarded as the inner surfaces of the bodies 130 of this group of memory cell layers. According to one embodiment, the gate structures 140 of the memory cells CM1 and CM2 are respectively located on the outer surfaces of the bodies 130, and the conductive portion CB is located between the inner surfaces of the bodies 130.

More specifically, taking the adjacent memory cell layers LM1 and LM2 as an example, as shown in FIG. 2, the gate structure 140 of the memory cell CM1 is located on the surface 1302 of the body 130, and the gate structure 140 of the memory cell CM2 is located on the surface 1301 of the body 130. The opposite surfaces (e.g., bottom and top surfaces) of the conductive portion CB are in direct contact with the surface 1301 of the body 130 of the memory cell CM1 and the surface 1302 of the body 130 of the memory cell CM2, respectively. Therefore, no dielectric layer (such as an oxide layer) or any other component is disposed between the conductive portion CB of the embodiment and the surfaces of the bodies 130 of the adjacent memory cell layers.

Furthermore, the plurality of bit lines BL extend along the direction D3 and are spaced apart from each other in the direction D2, and are respectively connected to the corresponding bodies 130 of the memory cell layers LM1-LM4, and define a stacked memory cell array of the embodiment with the memory cell layers LM1-LM4. The stacked memory cell array is, for example, located in the area A1 of the substrate 100.

According to some embodiments, in the same plane level, each memory cell layer (e.g., each layer of LM1-LM4) includes a plurality of memory cells arranged in an array. In the embodiment of FIG. 1, each memory cell layer includes (but is not limited to) 4 memory cells arranged in a 1×4 array. As shown in FIGS. 1 and 2, each bit line BL connects one side of the body 130 of each memory cell in each memory cell layer LM1-LM4. The bodies 130 connected by the bit lines BL are stacked in the direction D3, and upper and lower adjacent bodies 130 are separated by the insulating layer 110.

In some embodiments, the body 130 includes a silicon-based material or other suitable semiconductor material. The gate structure 140 includes a gate dielectric layer 141 and a gate electrode 142. The gate dielectric layer 141 is located on the surface 1301 or the surface 1302 of the body 130. The gate electrode 142 is located on the gate dielectric layer 141. According to the embodiment, no matter whether the gate structure 140 is located on the surface 1301 or the surface 1302 of the body 130, the gate dielectric layer 141 is located between the body 130 and the gate electrode 142 and is in direct contact with the body 130. The gate dielectric layer 141 includes, for example, silicon oxide, silicon nitride, other suitable materials or combinations thereof. The gate electrode 142 includes, for example, polysilicon or other suitable conductive materials. In the application of the semiconductor device of the embodiment as a three-dimensional DRAM, the gate structure 140 can be used as a word line.

The conductive portion CB may include metal or other low-resistance conductive materials, such as tungsten, copper, or other suitable conductive materials. In this embodiment, the conductive portion CB is a metal wire. Since the conductive portion CB of the embodiment is in contact with the bodies 130 of two adjacent memory cell layers, it can also be referred to as a common body metal line. The conductive portion CB and the gate electrode 142 may include different conductive materials. The resistance of the conductive portion CB is, for example, smaller than the resistance of the gate electrode 142.

Furthermore, one side of the body 130 may be connected to the bit line BL. The opposite ends of each body 130 respectively have a drain region 132 and a source region 134 located at two opposite sides of the gate structure 140. The drain region 132 and the source region 134 are respectively heavily doped regions, and the conductivity type of the dopant in the drain region 132 and the source region 134 is opposite to the conductivity type of the dopant in the body 130. For example, the body 130 of the NMOS device includes P-type dopants, the channel region 136 thereof is a P-type region, and the drain region 132 and the source region 134 located at opposite ends of the body 130 respectively include high-concentration N-type dopants. The portion of the body 130 between the drain region 132 and the source region 134 and below the gate structure 140 is the channel region 136. According to the embodiment, the transistor 120 includes the gate structure 140, the drain region 132, the source region 134, the channel region 136, and the conductive portion CB, and two adjacent transistors 120 share the conductive portion CB.

It is worth noting that, in the extension direction of the body 130 (e.g., the direction D1), the gate structure 140 and the conductive portion CB are both separated from the bit line BL. Although not shown in FIG. 2, the memory cell layers LM1 and LM2 are isolated from each other by the insulating layer. In addition, the insulating layer also fills the gaps between the bit line BL and the gate structure 140 and the conductive portion CB to electrically isolate these components.

To prevent the conductive portion CB from contacting the drain region 132 and the source region 134, the conductive portion CB may be located between the drain region 132 and the source region 134, and both sides of the conductive portion CB do not exceed the side edges of the drain region 132 and the source region 134. More specifically, the width of the conductive portion CB is preferably smaller than the width of the gate structure 140. As shown in FIG. 2, the gate structure 140 and the conductive portion CB respectively have a width W1 and a width W2 in the extension direction of the body 130, wherein the width W2 is smaller than the width W1. Furthermore, the gate structure 140 and the conductive portion CB have different spacings relative to the bit line BL. In some embodiments, the gate structure 140 is spaced apart from the bit line BL connected to the body 130 by a distance DW. The conductive portion CB is spaced apart from the bit line BL connected to the body 130 by a distance DM. The distance DM is greater than the distance DW.

In addition, according to some embodiments, the memory cell CM may further include an electronic component 160 electrically connected to the transistor 120. For example, one side of the body 130 is connected to the electronic component 160. The electronic component 160 is, for example, a storage capacitor. The storage capacitor can be controlled by the transistor 120. The storage capacitor may be formed by any known technique for making a capacitor structure. The transistor 120 may also be coupled to other types of electronic components 160, such as resistive random access memory (RRAM or ReRAM) or any other applicable electronic components.

When operating a memory cell of a conventional three-dimensional semiconductor device, after applying the required voltage to the bit line and the gates on the upper and lower sides of the body, positive charges accumulate in the body (e.g., between the drain and the source) because the body is in a floating state. When a memory cell is in the off state, if other adjacent memory cells are operated, the originally off memory cell will have current flowing due to the positive charge accumulated in the body, thereby changing the state of charge storage in the electronic components (such as storage capacitors) connected to the body, destroying the stored data and making the critical voltage of the memory cell unstable. This is called the body floating effect. These accumulated charges also generate leakage current when the three-dimensional semiconductor device is switched between on and off. According to the embodiment of the present disclosure, the conductive portion CB disposed on one of the surfaces (e.g., the surface 1301 or the surface 1302) of the body 130 is in direct contact with the body 130. The conductive portion CB is, for example, externally connected to a voltage source or grounded. Therefore, the body 130 of the embodiment is a non-floating body. When the three-dimensional semiconductor device of the embodiment is operated, the positive charges accumulated in the body 130 can be discharged from the body 130 through the conductive portion CB, so that the charge storage state in the capacitor structure is not destroyed or lost.

In addition, the thickness of the conductive portion CB of the embodiment is not particularly limited as long as the accumulated charges in the body 130 can be extracted. For each body 130 of the embodiment, the gate structure 140 is disposed on only one side, and only the conductive portion CB is disposed on the other side of the body 130. Adjacent memory cells can be arranged closer without the electronic components 160 contacting each other. For example, the distance between the memory cell layers LM1 and LM2 in the third direction D3 shown in FIG. 2 can be further reduced, thereby reducing the total thickness and volume of the three-dimensional semiconductor device.

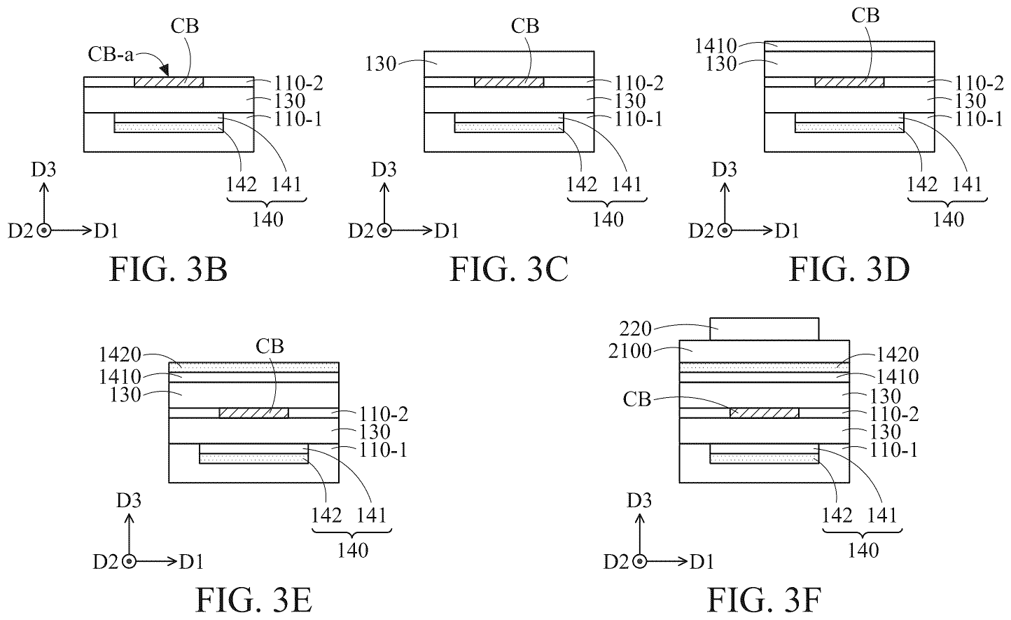

According to some non-limiting embodiments, a method for manufacturing a single memory cell of a three-dimensional semiconductor device with a horizontal word line stacking type is described below. The process diagrams of FIGS. 3A to 3I omit the substrate for the sake of clarity.

Referring to FIG. 3A, a body 130 is provided above a substrate (not shown), and one side of the body 130 includes a formed gate structure 140. For example, a gate dielectric layer 141 and a gate electrode 142 are formed on the surface 1302 of the body 130, and an interlayer dielectric layer 110-1 is deposited to cover the gate structure 140. Furthermore, a patterned conductive layer, such as a metal wire, is formed on the other side of the body 130, such as the surface 1301, to serve as the conductive portion CB of the embodiment. The conductive portion CB is in direct contact with the body 130, and extends in the direction D2, for example. The width of the conductive portion CB is smaller than the width of the gate electrode 142. Furthermore, a dielectric material 1100 is deposited on the conductive portion CB to cover the conductive portion CB.

Thereafter, referring to FIG. 3B, a portion of the dielectric material 1100 is removed, for example, by performing a planarization process, to expose the top surface CB-a of the conductive portion CB. The planarization process may be chemical mechanical polishing (CMP) or other suitable processes. The remaining portion of the dielectric material 1100 forms an interlayer dielectric layer 110-2.

Thereafter, referring to FIG. 3C, a body material layer, such as a silicon-based material layer, is grown on the interlayer dielectric layer 110-2 and the conductive portion CB. The body material layer is patterned to form a plurality of bodies 130 extending in a direction D1 and spaced apart in a direction D2. FIG. 3C only shows a cross section of one of the bodies 130. The conductive portion CB is located between two adjacent bodies 130 and is in direct contact with the surfaces of the two adjacent bodies 130.

Next, referring to FIG. 3D, a gate dielectric material 1410 is blanket deposited on the body 130. Referring to FIG. 3E, a gate electrode material 1420 is blanket deposited on the gate dielectric material 1410. Next, referring to FIG. 3F, a hard mask layer 2100 and a patterned photoresist layer 220 are sequentially disposed on the gate electrode material 1420. The hard mask layer 2100 includes, for example, a nitride layer, and the patterned photoresist layer 220 has a word line pattern of an embodiment.

Next, referring to FIG. 3G, the hard mask layer 2100 is etched through the patterned photoresist layer 220 to form a hard mask 210 having a word line pattern. Afterwards, the patterned photoresist layer 220 is removed. Next, the gate electrode material 1420 and the gate dielectric material 1410 below are etched through the hard mask 210 to form a gate dielectric layer 141 and a gate electrode 142 respectively. The gate dielectric layer 141 and the gate electrode 142 form a gate structure 140 above the body 130. The gate structure 140 extends in the direction D2, for example. Thereafter, referring to FIG. 3H, the hard mask 210 is removed. Referring to FIG. 3I, another interlayer dielectric layer 110-3 is deposited on the body 130 to cover the gate structure 140. The interlayer dielectric layers 110-1, 110-2, and 110-3 collectively form the insulating layer 110.

FIG. 3I shows a group of transistors of two adjacent memory cell layers according to some embodiments of the present disclosure, wherein the gate structures 140 are respectively located on the outer surfaces of the two bodies 130, and the conductive portion CB is located between the inner surfaces of the two bodies 130 and is in direct contact with the inner surfaces of the bodies 130. Afterwards, the next group of transistors can be manufactured on the interlayer dielectric layer 110-3 by referring to the above process steps, for example, repeating steps similar to those in FIGS. 3A to 3I to complete multiple groups of memory cell layers stacked in the direction D3, and forming multiple bit lines penetrating the memory cell layers and the insulating layer on the substrate, as well as other required components (such as body readout circuits, word-line readout circuits and other components, etc.) to complete the three-dimensional semiconductor device of the embodiment. In order to simplify the drawings and clearly illustrate the embodiments, the subsequent processes are omitted from drawing and detailed description.

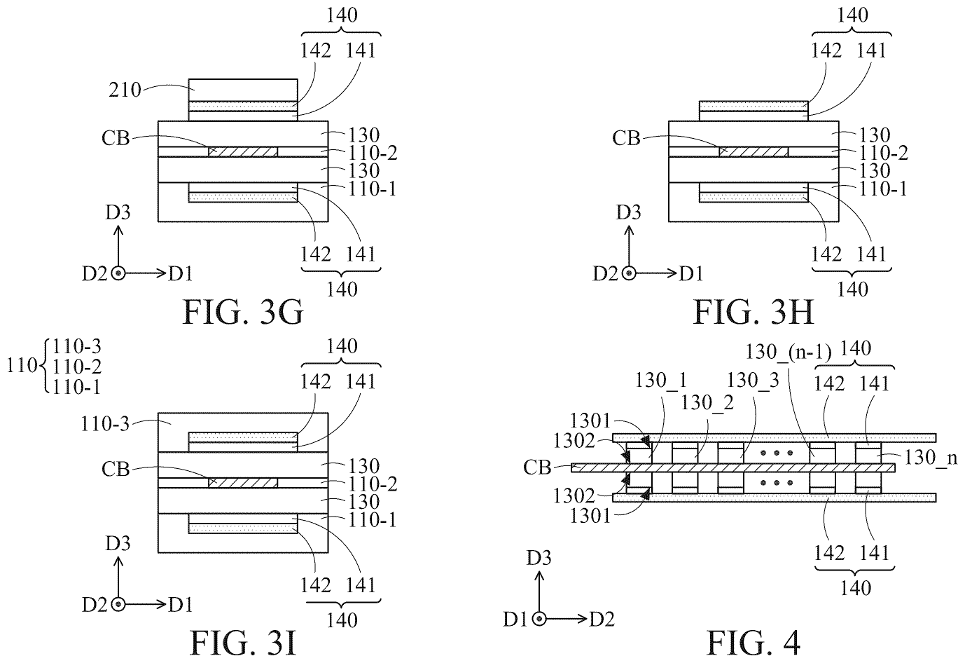

According to the above embodiment, the gate structure 140 and the conductive portion CB extend in the same direction. FIG. 4 is a schematic cross-sectional view of gate structures, conductive portions, and multiple bodies of adjacent memory cell layers in a semiconductor device according to some embodiments of the present disclosure. In the same memory cell layer, there are n bodies 130_1, 130_2, 130_3 . . . 130_(n−1), 130_n extending in, for example, a direction D1, and gate structures 140 and conductive portions CB perpendicular to the extending direction of the bodies (e.g., extending in a direction D2). The gate structures 140 and the conductive portions CB are respectively located on different sides of the bodies. More specifically, as shown in FIG. 4, a gate dielectric layer 141 is formed on the surfaces 1301 of the upper n bodies 130_1 to 130_n, and a continuous gate electrode 142 is formed on the gate dielectric layer 141 to serve as a word line of the upper memory cell layer. Another gate dielectric layer 141 is formed on the surfaces 1302 of the lower n bodies 130_1 to 130_n, and another gate electrode 142 is continuously formed on the gate dielectric layer 141 to serve as another word line of the lower memory cell layer. Furthermore, a continuous conductive portion CB is formed between the upper n bodies and the lower n bodies to directly contact the surfaces of the bodies.

According to some embodiments, since the surfaces 1301 of these bodies are on the same horizontal plane and the surfaces 1302 of these bodies are on another same horizontal plane, the relative surfaces of the conductive portion CB (such as the upper and lower surfaces shown in FIG. 4) can directly contact the surfaces of these bodies 130_1-130_n (such as the surfaces 1301 and the surfaces 1302) at the same horizontal height respectively to electrically connect these bodies 130_1-130_n.

In addition, according to the memory cell layers of the embodiment, the conductive portion CB and the gate electrode 142 (as a word line) of the gate structure 140 can extend to different regions of the substrate 100 respectively, and appropriate readout circuits can be configured for reading.

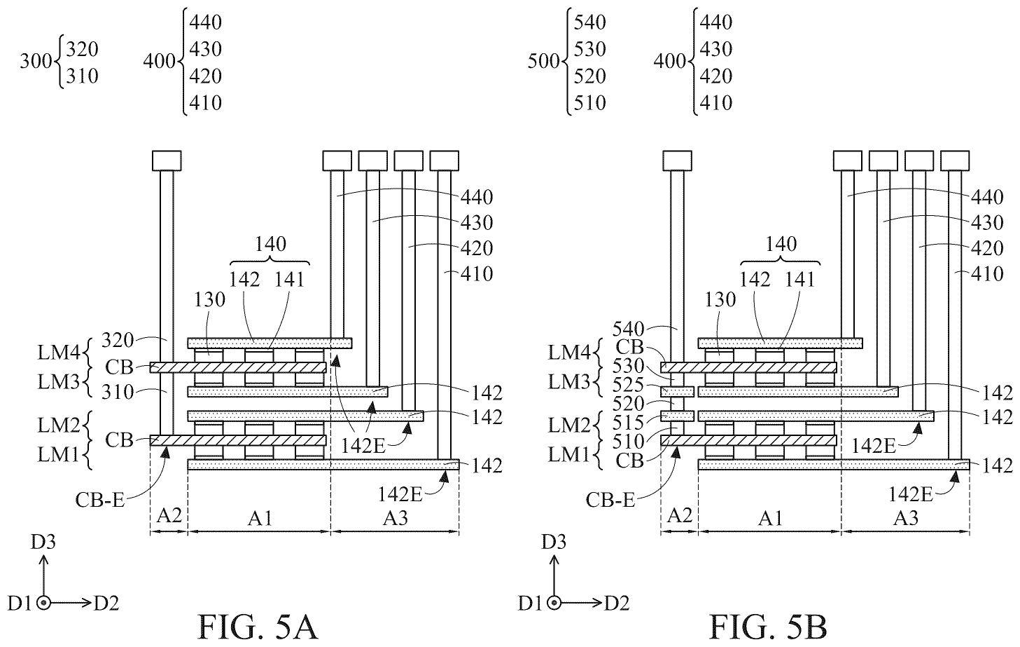

Referring to FIGS. 5A and 5B, which are schematic cross-sectional views of three-dimensional semiconductor devices according to some embodiments of the present disclosure. To simplify the drawings, FIGS. 5A and 5B do not show the substrate below the memory cell array and the insulating layer between the memory cell layers LM1-LM4. Furthermore, the substrate may include regions A1, A2 and A3, wherein the regions A2 and A3 are respectively located at two sides of the region A1. As described above, the stacked memory cell array including the memory cell layers LM1-LM4 (FIG. 1) is located in the region A1. The conductive portions CB of the memory cell layers LM1-LM4 extend to the region A2. The ends CB-E of the conductive portions CB are connected by vias in the region A2.

In the embodiment of FIG. 5A, the via 310 extends in a direction D3 and connects the ends CB-E of the two conductive portions CB. Furthermore, the via 310 extends in the direction D3 by the length of two memory cell layers and one insulating layer, and the extension length is defined as the depth of the via 310. Furthermore, the region A2 also includes a contact 320 extending in the direction D3. The contact 320 is electrically connected to the via 310 to form a body readout circuit 300.

In addition to the configuration of the body readout circuit 300 as shown in FIG. 5A, auxiliary vias and auxiliary conductive wires can also be appropriately arranged at positions closer to the substrate and/or in vias with longer extension lengths, so that the vias obtained still have a good profile even if they are located at a deeper bottom in the stacked structure.

The difference between FIG. 5B and FIG. 5A is that the via 310 in FIG. 5A is replaced by auxiliary vias 510, 520, and 530 and auxiliary conductive wires 515 and 525. Specifically, in the embodiment of FIG. 5B, the auxiliary vias 510, 520, and 530 extend in the direction D3. The auxiliary conductive wires 515 and 525 correspond to the levels of the gate electrodes 142 of the memory cell layers LM2 and LM3 respectively, but are electrically isolated from the gate electrodes 142. In practical applications, the auxiliary conductive wires 515 and 525 can be manufactured in the same conductive layer as the gate electrodes 142 of the memory cell layers LM2 and LM3. As shown in FIG. 5B, the auxiliary vias 510, 520, and 530 have the same depth, for example, they extend approximately the length of one memory cell layer and one insulating layer in the direction D3. Furthermore, according to the exemplary structure of FIG. 5B, the region A2 further includes a contact 540 electrically connected to the vias 510, 520, and 530 to form a body readout circuit 500. Specifically, through the body readout circuit 300 (FIG. 5A) and the body readout circuit 500 (FIG. 5B) of the embodiment, the conductive portions CB connected to the bodies 130 can lead out and remove the accumulated charges in the bodies 130.

More specifically, in some embodiments, the body readout circuits 300 and 500 may be grounded to remove accumulated charge within the bodies 130. In some other embodiments, the body readout circuits 300 and 500 may be electrically connected to a power supply component (not shown) to provide a suitable operating voltage. When the power supply component applies a bias to the body readout circuits 300 and 500, the accumulated charges in the bodies 130 can be eliminated and the threshold voltage of the memory cell array can be adjusted (e.g., increased) to reduce leakage current and improve the electrical performance of the application device.

Furthermore, according to the body readout circuits 300 and 500 provided in the embodiments, the ends CB-E of the conductive portions CB connected thereto may be substantially flush without being arranged in a stepped manner, thus not occupying additional lateral space of the substrate, and reducing the volume of the three-dimensional semiconductor device.

In the embodiments shown in FIGS. 5A and 5B, the substrate further includes the region A3 adjacent to the region A1. The gate electrodes 142 of the gate structures 140 of the memory cell layers LM1-LM4 extend into the region A3. The ends 142E of the gate electrodes 142 form a stepped configuration in the region A3. The region A3 also includes a plurality of contacts 410, 420, 430, and 440 extending in the direction D3. The contacts 410-440 are respectively electrically connected to the ends 142E of the gate electrodes 142 to form a plurality of word-line readout circuits 400. Since the ends 142E of the gate electrodes 142 are in a stepped configuration, the contacts 410-440 connected to the ends 142E can be spaced apart at appropriate intervals to avoid short-circuit of the word lines.

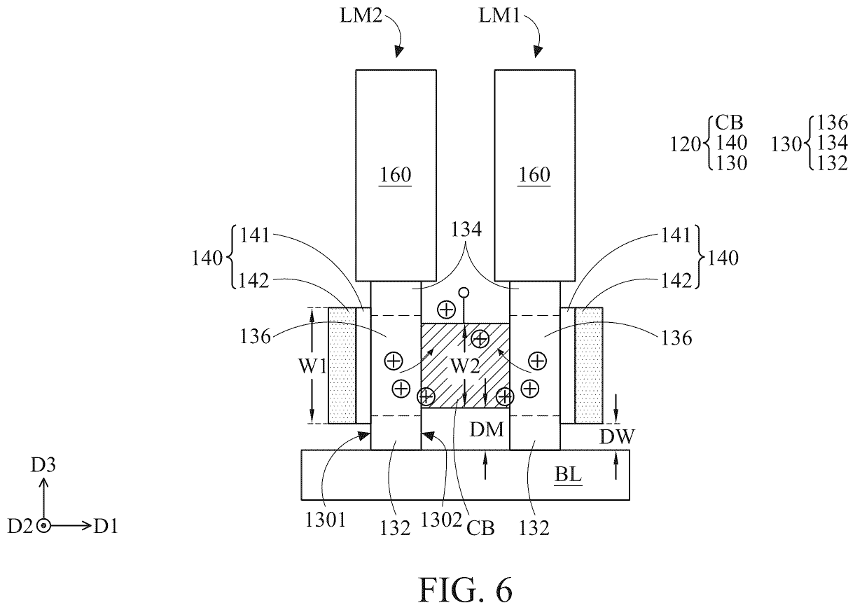

Furthermore, although the above embodiments are described with reference to a three-dimensional semiconductor device of a horizontal word line stacking type, the present disclosure can also be applied to a three-dimensional semiconductor device of a vertical word line stacking type. FIG. 6 is a schematic cross-sectional view of adjacent memory cells in a three-dimensional semiconductor device with a vertical word line stacking structure according to some embodiments of the present disclosure. To simplify the diagram, the substrate is omitted in FIG. 6. Furthermore, the same reference numbers are used for the components in FIG. 6 that are the same as those in FIGS. 1 and 2, and reference may be made to the descriptions of the contents of these components in the above embodiments, which will not be repeated here.

The difference between FIG. 6 and FIGS. 1 and 2 mainly lies in the configuration of the related components, for example, the bodies 130, the word lines (e.g., the gate structures 140), and the bit lines BL on the substrate.

Specifically, in the embodiment of the three-dimensional semiconductor device having the horizontal word line stacking type, as shown in FIGS. 1 and 2, the top surface of the substrate is, for example, parallel to the plane formed by the direction D1 and the direction D2. The surfaces 1301 and the surfaces 1302 of the bodies 130 are substantially parallel to the top surface of the substrate. The extending direction of the bit line BL is substantially perpendicular to the top surface of the substrate. In the embodiment of the three-dimensional semiconductor device having the vertical word line stacking structure, as shown in FIG. 6, the top surface of the substrate is, for example, parallel to the plane formed by the direction D2 and the direction D3. The surfaces 1301 and the surfaces 1302 of the bodies 130 are substantially perpendicular to the top surface of the substrate. The extending direction of the bit line BL is substantially parallel to the top surface of the substrate. Furthermore, the three-dimensional semiconductor device shown in FIG. 6 also includes a conductive portion CB located between adjacent memory cell layers such as LM1 and LM2 and directly contacting the surfaces of the bodies 130. The conductive portion CB may be used as a common body wire to improve the electrical performance of the semiconductor device. In FIG. 6, the configuration and materials of other components that are the same as those in FIG. 2 can be referred to the above descriptions in the embodiments and will not be repeated here.

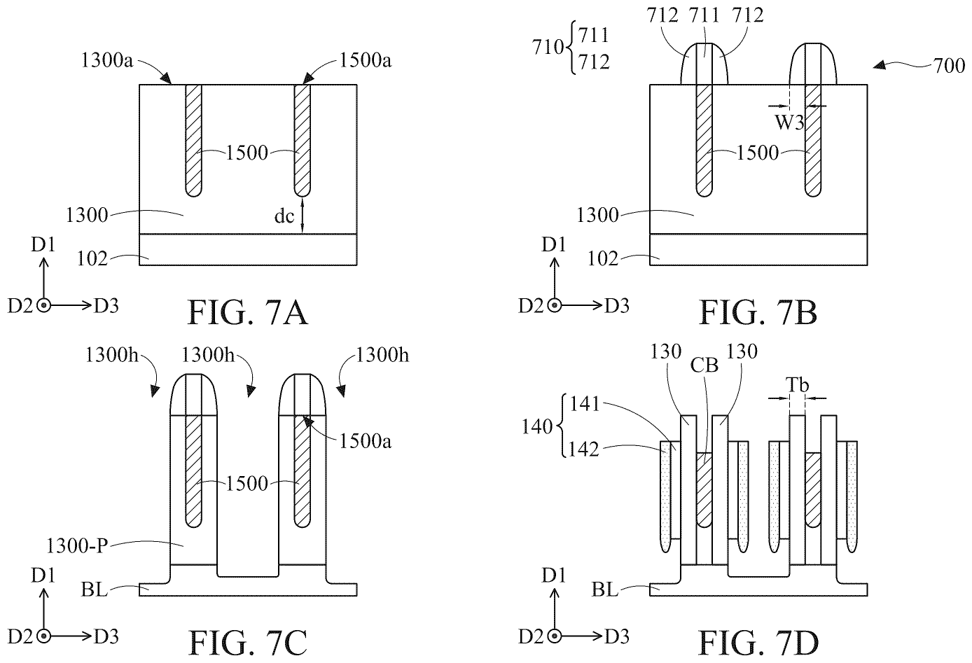

FIGS. 7A to 7D are schematic diagrams of two groups of adjacent memory cells of a three-dimensional semiconductor device at multiple intermediate manufacturing stages according to some embodiments of the present disclosure. The process diagram of this embodiment omits showing the substrate to facilitate clear description.

Referring to FIG. 7A, a first conductive material layer 102 and a body material layer 1300 are formed on a substrate (not shown). Afterwards, a plurality of grooves (not shown) spaced apart from each other in the direction D3 are etched in the body material layer 1300. A suitable conductive material is deposited on the body material layer 1300 to fill the grooves. A planarization process is then performed to remove excess conductive material, thereby forming second conductive material layers 1500 in the grooves.

As shown in FIG. 7A, the substrate of this embodiment is, for example, parallel to the plane formed by the direction D2 and the direction D3. Each second conductive material layer 1500 extends from the top surface 1300a of the body material layer 1300 toward the substrate. The bottom surface of the second conductive material layer 1500 is separated from the first conductive material layer 102 by a distance dc. Each second conductive material layer 1500 also extends in the direction D2. Furthermore, the top surface 1500a of the second conductive material layer 1500 may be coplanar with the top surface 1300a of the body material layer 1300. The first conductive material layer 102, for example, includes one or more conductive materials suitable for manufacturing a bit line. The body material layer 1300 is, for example, a silicon-containing material layer.

Referring to FIG. 7B, a hard mask 700 is formed on the body material layer 1300. The hard mask 700 includes a plurality of mask portions 710 corresponding to the second conductive material layers 1500. Each mask portion 710 can define the position of the body to be formed subsequently. Each mask portion 710 may include a core 711 and spacers 712 on both sides of the core 711. The core 711, for example, covers the top surface 1500a of the second conductive material layer 1500. The spacers 712 cover portions of the body material layer 1300 at the left and right sides of the second conductive material layer 1500. The bottom dimension of the spacer 712 has a width W3 in the direction D3, for example, which can control the thickness Tb (FIG. 7D) of the subsequently formed body 130 in the direction D3.

Afterwards, referring to FIG. 7C, an etching process is performed based on the hard mask 700 to remove a portion of the body material layer 1300 and a portion of the first conductive material layer 102 to form a plurality of grooves 1300h. The remaining portion 1300-P of the body material layer covers the side and bottom of the second conductive material layer 1500. The remaining portion of the first conductive material layer 102 forms a bit line BL. Thereafter, the hard mask 700 is removed to expose the top surface 1500a of the second conductive material layer 1500.

Referring to FIG. 7D, a portion of the second conductive material layer 1500 is removed, for example, by etching back or other suitable processes. The remaining portion of the second conductive material layer 1500 may serve as the conductive portion CB of the embodiment. The portion of the body material layer 1300-P between the second conductive material layer 1500 and the bit line BL is removed to isolate the conductive portion CB from the bit line BL. The remaining portion of the body material layer 1300-P is the body 130 of the embodiment. Afterwards, a gate structure 140 (including a gate dielectric layer 141 and a gate electrode 142) is formed on the outer surface (relative to the inner surface directly in contact with the conductive portion CB) of each body 130. Thereafter, a source region and a drain region (not shown) are formed in the body 130. An insulating layer (not shown) is formed over the substrate to cover the gate structures 140, the bodies 130, the conductive portions CB, and the bit line BL.

Based on the above, the three-dimensional semiconductor device provided in some embodiments of the present disclosure has many advantages. According to an embodiment, a common conductive portion, such as a common metal wire, may be disposed between bodies of adjacent memory cells of a three-dimensional semiconductor device so that accumulated charges in the bodies can be removed from the conductive portion during operation. Therefore, the non-floating body of the embodiment can avoid leakage current caused by accumulated charges when the semiconductor device is switched on and off, and maintain a good state of charge storage in the capacitor structure. The reduction of leakage current can lower the operating voltage of the three-dimensional semiconductor structure and reduce additional power loss, thereby realizing green semiconductor technology that saves energy and reduces carbon emissions. Furthermore, according to some embodiments, the common conductive portion may be externally connected to a voltage source, and the voltage source is different from the voltage source electrically connected to the gate structure. The voltage applied to the conductive portion can be used to change the bias applied to the body, thereby controlling the threshold voltage of the memory cell array in the three-dimensional semiconductor device and improving the electrical performance of the semiconductor device. In addition, compared to conventional MOS devices that use silicon materials, doped wells and heavily doped contacts to read the body, the conductive portion of the embodiment is in direct contact with the body surface, so that the accumulated charge can be removed from the body more quickly and voltage can be applied to the body more quickly. Furthermore, the semiconductor device provided in the embodiment only forms a gate structure on one side of the body, and thus only forms a gate dielectric layer on one side, which can reduce the distance between adjacent memory cell layers and further reduce the volume of the three-dimensional semiconductor device. Moreover, the embodiment omits the step of making a material layer such as a dielectric layer between the conductive portion and the body (the conductive portion is in direct contact with the body) in the manufacturing process, thereby reducing carbon emissions, and the use of water resources and chemicals in the production process, achieving energy conservation and carbon reduction, and implementing a green process.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A three-dimensional semiconductor device, comprising:
a plurality of memory cell layers and a plurality of insulating layers disposed in an alternating manner over a substrate;
a plurality of bit lines on the substrate and separated from each other, wherein the bit lines and the memory cell layers define an array of stacked memory cells comprising a plurality of memory cells, wherein each of the memory cells comprises:
a body on the substrate, wherein one side of the body is connected to one of the bit lines; and
a gate structure and a conductive portion on a first surface and a second surface of the body,
wherein the conductive portion is between adjacent memory cell layers and in direct contact with the body.

2. The three-dimensional semiconductor device as claimed in claim 1, wherein the gate structure and the conductive portion contacting the body have an extension direction that is different from that of the body, and the gate structure and the conductive portion respectively have a first width and a second width in the extension direction of the body, wherein the second width is smaller than the first width.

3. The three-dimensional semiconductor device as claimed in claim 1, wherein the gate structure and the conductive portion contacting the body are respectively separated from the bit line connected to the body in the extension direction of the body.

4. The three-dimensional semiconductor device as claimed in claim 3, wherein the gate structure is spaced apart from the bit line connected to the body by a first spacing, the conductive portion contacting the body is spaced apart from the bit line connected to the body by a second spacing, and the second spacing is greater than the first spacing.

5. The three-dimensional semiconductor device as claimed in claim 1, wherein opposite ends of the body have a drain region and a source region respectively, the body is below the gate structure, a portion of the body between the source region and the drain region is a channel region, and the gate structure, the drain region, the source region and the conductive portion contacting the body form a transistor.

6. The three-dimensional semiconductor device as claimed in claim 5, wherein the transistor is coupled to another electronic component, and the body is a non-floating body.

7. The three-dimensional semiconductor device as claimed in claim 1, wherein the gate structure is electrically connected to a first power supply component, and the conductive portion is electrically connected to a second power supply component that is different from the first power supply component.

8. The three-dimensional semiconductor device as claimed in claim 1, wherein the conductive portion is grounded.

9. The three-dimensional semiconductor device as claimed in claim 1, wherein the gate structure comprises:
a gate dielectric layer located on the first surface or the second surface of the body; and
a gate electrode located on the gate dielectric layer,
wherein the conductive portion and the gate electrode comprise different conductive materials.

10. The three-dimensional semiconductor device as claimed in claim 1, wherein the body comprises a silicon-based material, and the conductive portion is a metal conductor.

11. A three-dimensional semiconductor device, comprising:
a plurality of memory cell layers and a plurality of insulating layers disposed in an alternating manner over a substrate, wherein the memory cell layers comprise an array of stacked memory cells, and each layer of the memory cell layers comprises:
a plurality of bodies, each having a first surface and a second surface opposite to each other, wherein the bodies extend in a first direction and are spaced apart from each other in a second direction;
a gate structure extending in the second direction and located on the first surfaces of the bodies; and
a conductive portion extending in the second direction, wherein a surface of the conductive portion is in contact with the second surfaces of the bodies opposite the first surfaces,
wherein another surface of the conductive portion contacts a first surface of a body of an adjacent memory cell layer.

12. The three-dimensional semiconductor device as claimed in claim 11, wherein the gate structure and the conductive portion have a first width and a second width respectively in the first direction, and the second width is smaller than the first width.

13. The three-dimensional semiconductor device as claimed in claim 11, wherein the conductive portion extending in the second direction contacts the second surfaces of the bodies at the same level.

14. The three-dimensional semiconductor device as claimed in claim 11, wherein the gate structure comprises:
a gate dielectric layer, located on the first surfaces of the bodies and directly contacting the first surfaces; and
a gate electrode, located on the gate dielectric layer,
wherein there is no dielectric layer between the conductive portion and the bodies of two adjacent memory cell layers.

15. The three-dimensional semiconductor device as claimed in claim 11, wherein the substrate comprises a first region and a second region adjacent to the first region, the array of stacked memory cells is located in the first region, the conductive portions of the memory cell layers extend into the second region of the substrate, and ends of the conductive portions are connected to each other by vias in the second region.

16. The three-dimensional semiconductor device as claimed in claim 15, wherein a plurality of auxiliary vias are between the ends of two adjacent conductive portions, the adjacent auxiliary vias are connected by an auxiliary wire, the auxiliary wires are respectively in the same layer as the gate electrodes of the gate structures of the memory cell layers, but are electrically isolated from the gate electrodes of the gate structures.

17. The three-dimensional semiconductor device as claimed in claim 15, further comprising a contact located in the second region, wherein the contact electrically connects the conductive portions and the vias to form a body readout circuit.

18. The three-dimensional semiconductor device as claimed in claim 17, further comprising a power supply component electrically connected to the body readout circuit, wherein when the three-dimensional semiconductor device is operated, the power supply component applies a bias voltage to the body readout circuit.

19. The three-dimensional semiconductor device as claimed in claim 17, wherein the body readout circuit is grounded.

20. The three-dimensional semiconductor device as claimed in claim 11, further comprising a plurality of bit lines located on the substrate and extending along a third direction, wherein the bit lines are spaced apart from each other in the second direction, and the bit lines are respectively connected to the bodies of the memory cell layers to define the array of stacked memory cells comprising a plurality of memory cells.
